(19) United States
(12) Patent Application Publication
(10) Pub. No.: US 2010/0275994 A1
(43) Pub. Date: Nov. 4, 2010

(54) SPECTRUM MANIPULATION DEVICE AND METHOD

(75) Inventor: Levi SCHACHTER, Haifa (IL)

Correspondence Address: Marc Van Dyke, 123 N.W. 13th Street, Suite 221, Boca Raton, FL, 33432-1619, US

(73) Assignee: TECHNION-RESEARCH & DEVELOPMENT FOUNDATION LTD.[IL /IL], Haifa (IL)

(21) Appl. No.: 12/837,401

(22) Filed: Jul. 15, 2010

Related U.S. Application Data
(63) Continuation-in-part of application No. PCT/IL2009/000069, filed on Jan. 18, 2009.

(51) Int. Cl. H01L 31/0232; G02F 2/02

(52) U.S. Cl. 136/257; 359/326

(57) ABSTRACT

A spectrum manipulation device and method for increasing an energy conversion efficiency of a photovoltaic cell arrangement, the device including: (a) a black body adapted to absorb an input electromagnetic energy having an input energy flux spectrum, and to emit a first output electromagnetic energy having a different, output energy flux spectrum; (b) a transparent cover, adapted to thermally insulate the black body from an ambient environment, and to receive light and direct the light towards the black body; (c) an optical device, facing the black body, and adapted to: (i) receive the first output energy and emit a second output electromagnetic energy having a narrow, modified energy flux spectrum, with respect to the output energy flux spectrum, and (ii) recycle some of the first output electromagnetic energy to the black body; (d) a photovoltaic cell having a photon absorption surface, disposed to be in optical communication with the optical device, and (e) a housing containing the black body and the optical device, and adapted to thermally insulate the black body and to fix a position of the black body with respect to the optical device, the optical device further adapted to direct the second output energy towards the photon absorption surface.

### CROSS-REFERENCE TO RELATED APPLICATIONS

This patent application is a continuation-in-part of PCT/IL2009/000069 filed on Jan. 18, 2009 and published as WO/2009/090653, and claims priority to U.S. Provisional Patent Application 61/021,463 filed on Jan. 16, 2008, which are all hereby incorporated in their entirety by reference.

### FIELD AND BACKGROUND OF THE INVENTION

The present invention relates to spectrum manipulation and, more particularly, to a spectrum manipulation device and method for increasing the efficiency of solar cell arrangements.

More energy from sunlight strikes the Earth in one hour (4.3×1020 J) than all the energy consumed on the planet in a year (4.1×1020 J). Although, as of 2001, solar electricity was a $7.5 billion industry growing at a rate of 35-40% per annum, solar electricity provided less than 0.1% of the world's electricity. The huge gap between the present use of solar energy and the enormous undeveloped potential thereof defines a major challenge in energy research. Covering 0.16% of the land on Earth with 10% efficient solar conversion systems would provide 20 TW of power, nearly twice the world's consumption rate of fossil energy.

However, the cost per watt of delivered electricity produced from solar light, for example, by means of photovoltaic cells, needs to be significantly reduced, to economically compete with primary fossil energy.

A state-of-the art report of the Basic Energy Sciences Workshop on Solar Energy Utilization (“Basic Research Needs for Solar Energy Utilization”, U.S. Department of Energy, Apr. 18-21, 2005; http://www.sc.doe.gov/bes/reports/files/SEU_rpt.pdf) provides an overview of key scientific challenges and research directions that may enable efficient and economic use of the solar resource to provide a significant fraction of global primary energy by the mid-21st century.

Among the various solar conversion systems, photovoltaic (PV) cells play a prominent role. D. Chapin, et al. [“A New Silicon p-n Junction Photocell for Converting Solar Radiation into Electrical Power,” J. Appl. Phys. 25, 676 (1954)] teaches the use of a p-n junction in single-crystal Si, and discloses an efficiency of 5-6%. This type of solar cell continues to be important in the commercial photovoltaic cell market, as is evident from Table 1.

TABLE 1
Worldwide PV Module Production in 2003 by Technology
Type (PV News)

| PV Technology Type | Power [MW] | % of PV Power |
|---|---|---|
| Flat plates - single-crystal | 230.5 | 31 |
| silicon | | |
| Cast poly/multicrystalline | 443.8 | 59.6 |
| silicon | | |
| Ribbon silicon | 22.8 | 3.1 |
| Thin-film amorphous silicon | 39.3 | 5.3 |
| Thin-film cadmium telluride | 3 | 0.4 |
| Thin-film Copper indium | 4 | 0.5 |
| gallium (di)selenide (CIGS) | | |
| Concentrators - silicon | 0.7 | 0.1 |
| TOTAL | 744.1 | 100 |

To better compete with primary fossil energy, it would be highly advantageous to reduce the current cost/watt of delivered solar electricity by a factor of 25-50. Reducing the cost, increasing the lifetime, and improving the energy efficiency of the PV system may help to achieve this.

One way of potentially increasing conversion efficiency is by way of spectrum manipulation. In two articles, Trupke et al. [“Improving Solar Cell Efficiencies by Down-conversion of High-energy Photons,” and “Improving Solar Cell Efficiencies by Up-conversion of Sub-band-gap Light,” J. Appl. Phys. 92, 1668 and 92, 4117 (2002)] demonstrate the advantage of down and up-conversion of the photons that are not absorbed by the photovoltaic cell. Optical frequency shifting cells involve the transformation of the solar spectrum from one with a broad range of energies to one with the same power density but a narrow range of photon energies. One central feature of these approaches is that the transformation of the solar spectrum is done separately with non-linear materials that are not part of the actual solar cell, thus increasing the efficiency of an existing solar cell structure by means of additional coatings or external elements.

A schematic, conceptual illustration of a frequency conversion is provided in FIG. 1. A portion of the higher wavelength, sub-band-gap photons is up-converted to higher-energy photons, which may then be utilized by the photovoltaic cell.

In practice, the transformation of the solar spectrum using non-linear elements may be effective for rather narrow photon energy ranges. Consequently, a large number of such elements may be required to cover a broad spectral range.

It is believed that there is room and need for further improvements in the harnessing of solar energy by photovoltaic cells, and the subject matter of the present disclosure and claims is aimed at fulfilling this need.

### SUMMARY OF THE INVENTION

According to the teachings of the present invention there is provided a spectrum manipulation device for increasing an energy conversion efficiency of a photovoltaic cell arrangement, including: (a) a black body adapted to absorb an input electromagnetic energy having an input energy flux spectrum, and to emit a first output electromagnetic energy having a different, output energy flux spectrum; (b) a solid, at least partially transparent cover, facing a first side of the black body, the cover adapted to thermally insulate the black body from an ambient environment, and to receive light and direct the light towards the black body; (c) an optical device or filter arrangement, facing a second side of the black body, and adapted to: (i) receive the first output energy and emit a second output electromagnetic energy having a narrow, modified energy flux spectrum, with respect to the output energy flux spectrum of the black body, and (ii) recycle at least a portion of the first output electromagnetic energy to the black body; (d) at least one photovoltaic cell having a photon absorption surface, the surface disposed to be in optical communication with the optical filter arrangement, and (e) a housing containing at least the black body and the optical filter arrangement, the housing adapted to thermally insulate the black body and to fix a position of the black body with respect to the optical filter arrangement, the optical filter arrangement being further adapted to direct the second output energy towards the photon absorption surface.

According to another aspect of the present invention there is provided a spectrum manipulation device including: (a) a black body adapted to absorb an input electromagnetic energy having an input energy flux spectrum, and to emit a first output electromagnetic energy having a different, output energy flux spectrum; (b) a solid, at least partially transparent cover, facing a first side of the black body, the cover adapted to thermally insulate the black body from an environment, and to receive light and direct the light towards the black body; (c) an optical filter arrangement, facing a second side of the black body, and adapted to: (i) receive the first output energy; (ii) recycle at least a portion of the output electromagnetic energy to the black body, and (iii) emit a second output electromagnetic energy having a narrow, modified energy flux spectrum, with respect to the output energy flux spectrum of the black body, and (d) a housing containing at least the black body and the optical filter arrangement, the housing adapted to thermally insulate the black body and to fix a position of the black body with respect to the optical filter arrangement.

According to yet another aspect of the present invention there is provided a spectrum manipulation device including: (a) a black body adapted to absorb an input electromagnetic energy having an input energy flux spectrum, and to emit a first output electromagnetic energy having a different, output energy flux spectrum; (b) a solid, at least partially transparent cover, facing a first side of the black body, the cover adapted to thermally insulate the black body from an environment, and to receive light and direct the light towards the black body; (c) an optical filter arrangement, facing a second and typically substantially opposite side of the black body, and adapted to: (i) receive the first output energy; (ii) recycle at least a portion of the output electromagnetic energy to the black body, and (iii) emit a second output electromagnetic energy having a narrow, modified energy flux spectrum, with respect to the output energy flux spectrum of the black body; (d) a housing containing at least the black body and the optical filter arrangement, the housing adapted to thermally insulate the black body, and (e) a first sealed volume, disposed and thermally insulating between the black body and the cover, the sealed volume having a subatmospheric pressure below 0.1 torr.

According to yet another aspect of the present invention there is provided a method of increasing an energy conversion efficiency of a photovoltaic cell arrangement, the method including the steps of: (a) providing the device; (b) disposing the device whereby the black body absorbs, from solar light, the input electromagnetic energy, and emits the first output electromagnetic energy; (c) processing the first output energy in the filter arrangement to emit the second output electromagnetic energy having the modified spectrum and a third output electromagnetic energy; (d) conveying the second output energy to the photovoltaic cell, and (e) recycling at least a portion of the third output energy to the black body.

According to further features in the described preferred embodiments, the device further includes a first sealed volume, disposed and thermally insulating between the black body and the cover, the sealed volume having a subatmospheric pressure below 10⁻⁴ torr .

According to still further features in the described preferred embodiments, the device further includes a subatmospheric sealed volume, disposed and thermally insulating between the black body and the optical filter arrangement, the subatmospheric sealed volume having a subatmospheric pressure below 10⁻⁴ torr.

According to still further features in the described preferred embodiments, the optical filter arrangement includes a Bragg filter.

According to still further features in the described preferred embodiments, the device further includes a substantially transparent concentrating element, disposed whereby the cover is optically between the concentrating element and the black body, the concentrating element adapted to concentrate sunlight and to direct the sunlight to the cover.

According to still further features in the described preferred embodiments, the black body is a mesoscopic black body having a thickness below 100 micrometers.

According to still further features in the described preferred embodiments, the black body is a mesoscopic black body having a plurality of nanostructures.

According to still further features in the described preferred embodiments, the black body includes a material of construction selected from the materials consisting of tungsten, titanium, molybdenum, carbon, and a ceramic material.

According to still further features in the described preferred embodiments, the black body includes an inorganic carbide.

According to still further features in the described preferred embodiments, the housing includes a solid material behaving as a solid at a temperature of up to at least 900K.

According to still further features in the described preferred embodiments, the housing has an inner surface contacting the black body, the inner surface having a heat transfer coefficient below 2.0 Wm⁻¹K⁻¹ at 300K, and more preferably, below 0.5 Wm⁻¹K⁻¹.

According to still further features in the described preferred embodiments, the housing includes at least one ceramic material.

According to still further features in the described preferred embodiments, the ceramic material includes a ceramic oxide.

According to still further features in the described preferred embodiments, the ceramic oxide is selected from the group of ceramic oxides consisting of alumina, zirconia, and magnesia.

According to still further features in the described preferred embodiments, the cover includes a Bragg filter.

According to still further features in the described preferred embodiments, a grating is disposed on a surface of the black body.

According to still further features in the described preferred embodiments, the grating is optically disposed between the black body and the optical filter arrangement.

According to still further features in the described preferred embodiments, the optical arrangement is adapted whereby at least 80% of the modified energy flux spectrum lies within a range of 0.4 eV.

According to still further features in the described preferred embodiments, the optical arrangement is adapted whereby at least 80% of the modified energy flux spectrum lies within a range of 0.2 eV.

According to still further features in the described preferred embodiments, the optical arrangement is adapted whereby at least 90% of the modified energy flux spectrum lies within a range of 0.3 eV.

According to still further features in the described preferred embodiments, the optical filter arrangement is adapted whereby the range of 0.4 eV is substantially above an energy gap of the photovoltaic cell.

According to still further features in the described preferred embodiments, the at least a portion of the third output energy is at least 20%, preferably, at least 40%, and more preferably, at least 50% of the third output energy.

According to still further features in the described preferred embodiments, the operating temperature of the black body is at least 1200K.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice. Throughout the drawings, like-referenced characters are used to designate like elements.

In the drawings:

FIG. 1 schematically shows an idealized frequency up-conversion of the solar spectrum, according to a prior-art conception;

FIG. 2 is a block diagram of one embodiment of the inventive spectrum conversion apparatus, in which a black-body absorber/emitter is used as a spectrum converter;

FIG. 3 is a theoretical, graphical representation of electromagnetic energy flux spectra emitted by a black-body, as a function of black-body temperature;

FIG. 4 is a schematic side view of one embodiment of the inventive spectrum conversion apparatus, housed in a thermally-insulating housing;

FIG. 5 is a schematic top view of the apparatus of FIG. 4, and

FIG. 6 is a schematic, graphical representation of the multiple-stage conversion of the solar spectrum to a preferred spectrum for a photovoltaic cell, according to an exemplary embodiment of the present invention.

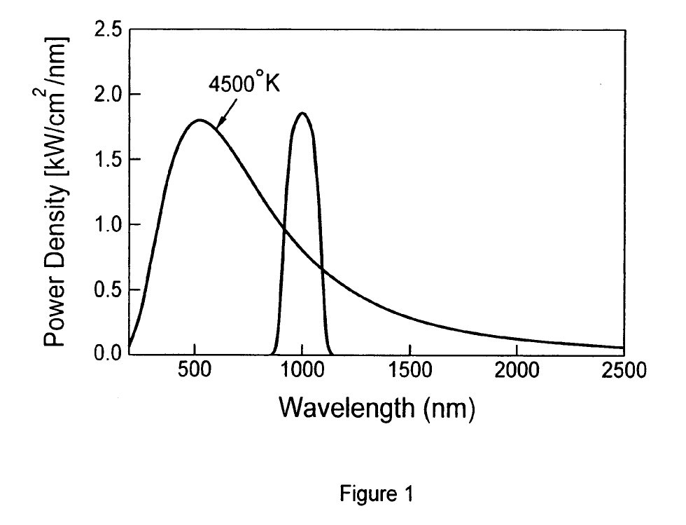

### DESCRIPTION OF THE PREFERRED EMBODIMENTS

The principles and operation of the black-body spectrum conversion apparatus and method according to the present invention may be better understood with reference to the drawings and the accompanying description.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

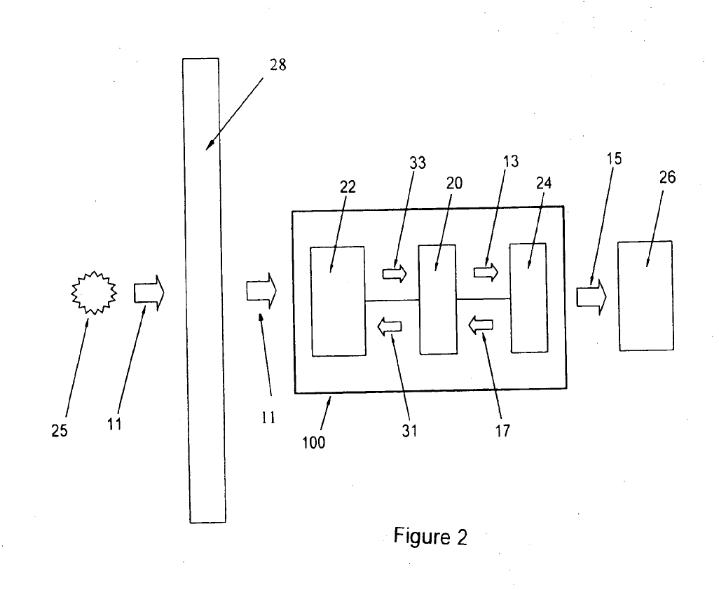

Referring now to the drawings, FIG. 2 is a schematic representation of one embodiment of the inventive spectrum conversion apparatus 100, in which a black-body absorber/emitter is used as a converter. Apparatus 100 may include a black body 20, at least a first optical device 22 that may be disposed between a solar light source (such as sunlight) 25 and black body 20, and at least a second optical device 24 disposed between black body 20 and at least one photovoltaic cell 26.

Electromagnetic radiation 11, emanating from a solar light source such as sun 25 and having a first characteristic spectrum, is absorbed by black body 20, typically operating at a temperature of at least 1200K, more typically, at least 1500K, still more typically, at least 1800K, and most typically, at least 2200K. Black body 20 emits electromagnetic radiation 13 having a second characteristic spectrum (the properties of which depend, inter alia, on the temperature of black body 20). Electromagnetic radiation 13 is subsequently processed or filtered by optical device 24, which is adapted to provide photovoltaic cell 26 with electromagnetic radiation 15 having a third characteristic spectrum. This spectrum is narrow with respect to the second characteristic spectrum. Preferably, optical device 24 is adapted to provide photovoltaic cell 26 with electromagnetic radiation 15 having a third characteristic spectrum associated with a predetermined energy level aimed to increase or substantially maximize the emerging power conversion of cell 26, and/or to reduce or substantially minimize the temperature increase of cell 26.

Optical device 24 further serves to return, to black body 20, electromagnetic radiation 17 that is not passed through to photovoltaic cell 26. Electromagnetic radiation 17 may include low energy radiation having energies below the energy threshold of electromagnetic radiation 15, and may also include high energy radiation having energies exceeding the energy threshold of electromagnetic radiation 15. In this manner, electromagnetic radiation 17 may be recycled, and may advantageously serve to heat black body 20.

By recycling electromagnetic radiation 17 to black body 20, the radiation is absorbed and recovered by black body 20, which in turn emits electromagnetic radiation 13, whose properties depend on the temperature and surface topology of black body 20. By sharp contrast, in conventional photovoltaic systems such as silicon-based PV cells, photons having energies below the energy gap may disadvantageously heat the PV cells, resulting in degradation of the PV cell operation. Moreover, even photons having energies above the energy gap may deliver their excess energies to the PV cells in the form of heat, which again results in degradation of PV cell operation.

Black body 20 may emit electromagnetic radiation 31 in a direction other than the direction of optical device 24. First optical device 22, which may be disposed between solar light source 25 and black body 20, may advantageously be adapted to return the energy in the form of electromagnetic radiation 33 to black body 20. Optical device 22 may also enable electromagnetic radiation 11 from solar light source 25 to pass through towards black body 20, with a minimum or otherwise low incidence of reflection.

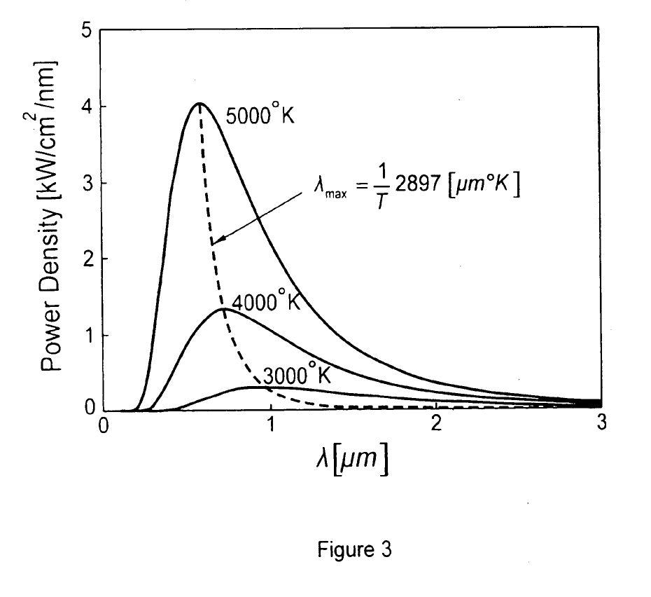

The spectrum of electromagnetic radiation 13 depends on the operating temperature of black body 20. FIG. 3 is a graphical theoretical representation of the power density of electromagnetic spectra (or energy flux spectra) emitted by a black-body having a smooth surface, as a function of wavelength, for several exemplary black-body temperatures. The dashed curve delineates the peak wavelength of the spectrum as a function of temperature.

The actual operating temperature of black body 20 may depend, inter alia, on the desired spectrum for photovoltaic cell 26, and on various temperature dependent structural limitations of the materials of construction. In some applications, the operating temperature of black body 20 is at least 1500K to 3300K or more, depending on the energy band requirement of the particular PV cell used, and on limitations of the materials of construction.

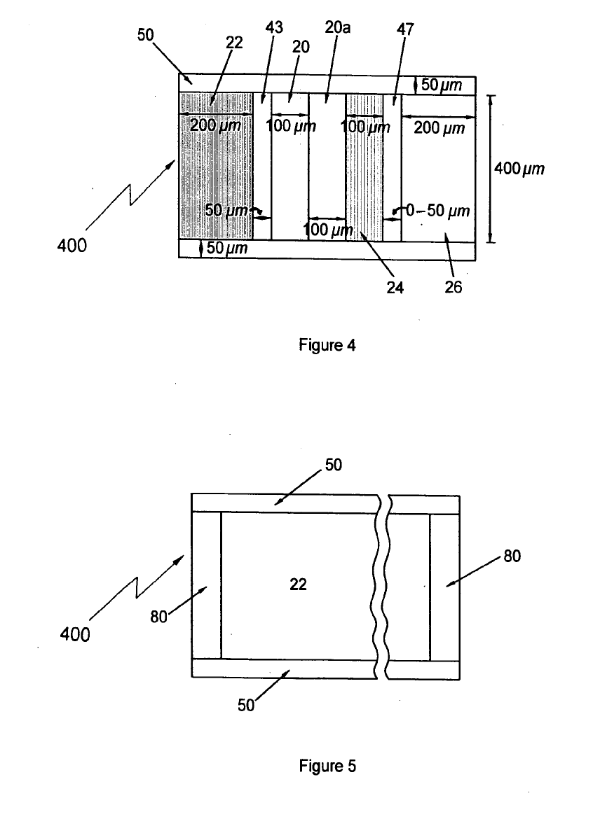

FIG. 4 is a schematic side view of one embodiment of an inventive spectrum conversion apparatus or device 400, housed in a thermally-insulating housing 50. Optical device 22, black body 20, optical device 24, and photovoltaic cell 26, may all be in-line, and may preferably be held in fixed position, with respect to one another, by housing 50.

Between optical device 22 and black body 20 may be disposed a sealed volume 43, preferably having a subatmospheric pressure of less than 0.1 torr, more preferably, less than 10⁻⁴ torr, and yet more preferably, less than 10⁻⁸ torr. Typically, the pressure is less than 10⁻⁹ torr, or 10⁻¹⁰−10⁻¹¹ torr or less. Such subatmospheric pressure advantageously insulates between black body 20 and optical device 22, and reduces heat loss to the environment.

Similarly, between optical device 24 and black body 20 may be disposed a sealed volume 45, preferably having a subatmospheric pressure of less than 0.1 torr, more preferably, less than 10⁻⁴ torr, and yet more preferably, less than 10⁻⁸ torr. Typically, the pressure is less than 10⁻⁹ torr, or 10⁻¹⁰−10⁻¹¹ torr or less. Such subatmospheric pressure advantageously insulates between black body 20 and optical device 24, and reduces heat loss to the environment.

Between optical device 24 and photovoltaic cell 26 may be disposed a volume 47, which may be sealed.

Thermally-insulating housing 50 may be of rigid construction, to fix in relative position optical device 22, black body 20, and optical device 24. Thermally-insulating housing 50 may also fix the position of photovoltaic cell 26 with respect to optical device 24. At least a portion of an inner wall 62 of housing 50 may contact black body 20, and is preferably adapted to thermally insulate black body 20.

The heat transfer coefficient of inner wall 62 may preferably be below 2.0 Wm¹K⁻¹ at 300K, and more preferably, below 0.5 Wm⁻¹K⁻¹. Inner wall 62 may advantageously include, or essentially consist of, ceramic materials, such as alumina, zirconia, magnesia, and/or other materials that are stable at high temperature and are preferably good thermal insulators.

Black body 20 may be a macroscopic black body structure, or a mesoscopic black body structure. Tungsten, having a dark, steel-gray color and a melting point of approximately 3695K, may be a particularly suitable material of construction. Tungsten filaments are extensively used in incandescent light bulbs, in which an electrical current may heat the filament to 2000K to 3300K, depending upon the type, shape, and size of the filament, and upon the amount of current drawn. The heated filament acts as a black body, emitting light that approximates a continuous spectrum.

In incandescent light bulbs, the useful part of the emitted energy is solely the visible spectrum, and typically, most energy is given off as heat in the near-infrared wavelengths. In the present invention, however, the waste energy is recycled: at least a portion, and preferably, substantially all of the photons having unsuitable wavelengths for the PV cells are returned to the black body, as described hereinabove.

Other materials of construction for black body 20 will be apparent to those skilled in the art. Such materials may include various carbides such as titanium carbide, silicon carbide, and tungsten carbide, various ceramic materials, and various forms of carbon suitable for high-temperature operation.

Mesoscopic black body structures may include various thin films or nanostructures such as inorganic nanotubes or inorganic nanofilaments. The films and nanostructures may include materials such as tungsten, titanium, molybdenum, carbon, and various carbides.

Optical device 22 may be substantially transparent. Preferably, optical device 22 may be adapted to reflect less than 20%, more preferably, less than 10%, and yet more preferably, less than 5% of the impinging solar light. In some cases, optical device 22 may be adapted to reflect less than 2%, or even less than 1% of the impinging solar light.

Optical device 22 is preferably a good thermal insulator, having a heat transfer coefficient below 3.0 Wm⁻¹K⁻¹ at 300K, and more typically, below 2.0 Wm⁻¹K⁻¹. Glasses and transparent or substantially transparent sintered ceramics may be suitable for optical device 22. Various specific materials of construction for optical device 22 will be apparent to those skilled in the art.

Optical device 22 may advantageously be adapted to return the energy (in the form of electromagnetic radiation 31) from black body 20, to black body 20, as electromagnetic radiation 33. To this end, optical device 22 may include, by way of example, a Bragg filter, preferably designed accounting for the operating temperature of the black body. Such a design involves a tradeoff between two contradicting constraints or preferred criteria: achievement (as close as practically possible) of 100% transparency with respect to sunlight, and achievement (as close as practically possible) of 100% reflection with respect to blackbody radiation 31.

Concentrating element or assembly 28 may advantageously be disposed above optical device 22, i.e., between the solar light source and optical device 22, to concentrate the electromagnetic radiation provided to optical device 22. Typically, concentrating element or assembly 28 may concentrate the electromagnetic radiation by a factor of at least 1.1, more typically, by a factor of at least 2, and more typically, by a factor of at least 10 or 50 to 10000 or more. Concentrating element or assembly 28 may be selected from various known or commercially available concentrators.

Optical device 24 may advantageously include photonic crystal elements such as a multilayer reflection coating or Bragg filter.

An optical Bragg filter is a transparent device with a periodic variation of the refractive index, so that a large reflectivity may be reached in some wavelength range (bandwidth) around a certain wavelength, provided each layer is of the order of quarter wavelength in the medium:

d λ/(4n)

where d is the thickness of each layer, λ is the vacuum wavelength of light, and n is the refractive index of the particular layer.

One exemplary embodiment of a Bragg filter has a plurality of pairs of alternate layers of silicon and silicon dioxide. Typically, 5-50 of such pairs may be used in a device such as optical device 24. Other materials may be more suitable for use in conjunction with silicon-based photovoltaic cells. Common optical coating materials for constructing such layers may include oxides such as SiO₂, TiO₂, Al₂O₃ and Ta₂O₅, and fluorides such as MgF₂, LaF₃ and AlF₃.

Optical device 24 is adapted to receive the output energy from blackbody 20, and to emit electromagnetic energy having a narrow, modified energy flux spectrum, with respect to that output energy. Preferably, at least 80% of the energy flux spectrum that is output by optical device 24 lies within a narrow range of 0.4 eV, more preferably, within a range of 0.3 eV, and most preferably, within a range of 0.2 eV. Yet more preferably, at least 90% of the energy flux spectrum lies within these ranges. Optical device 24 may be adapted such that this range is above or substantially above an energy gap of the specific photovoltaic cell employed.

With regard to dimensions, optical device 22 may have a thickness of at least 30 micrometers, and more typically, at least 100 micrometers. The thickness may be largely dictated by thermal insulation considerations. The maximum requisite thickness may be about 1000 micrometers.

Optical device 24 may have a thickness of at least 20 micrometers, and more typically, at least 50 micrometers. The thickness may be largely dictated by the materials selected, and by the tradeoff between filter efficiency and cost. The maximum requisite thickness is envisioned to be about 300 micrometers.

With regard to black body 20: the mesoscopic arrangement typically has a thickness of less than 5 micrometers, more typically, less than 1 micrometer, and in some cases, less than 0.1 micrometers; the macroscopic arrangement typically has a thickness of less than 100 micrometers, more typically, less than 50 micrometers, and most typically, in a range of 10 to 50 micrometers.

In FIG. 4, the exemplary thicknesses of optical device 22, black body 20, and optical device 24 are 200 micrometers, 100 micrometers and 100 micrometers, respectively. The exemplary thickness of photovoltaic cell 26 is 200 micrometers.

Sealed volumes 43 and 45 may have a thickness or an average thickness of at least 5 micrometers, at least 10 micrometers, or at least 20 micrometers. Typically, sealed volumes 43 and 45 may have a thickness or an average thickness of 20 to 200 micrometers, depending, inter alia, on the depth of the vacuum within the respective volumes, and the desired black body temperature. These thicknesses may apply at room temperature and/or under operating conditions.

Optical device 22, black body 20, and optical device 24 may have a length (long dimension) of up to several tens of centimeters. The length is usually determined to match the photovoltaic panel or unit, which may have a length of 10 to 30 centimeters or more.

FIG. 5 is a schematic top view of apparatus or device 400 of FIG. 4, in which the short dimension of the apparatus is sealed and insulated at each end by housing 50, and in which the long dimension of the apparatus is sealed and insulated on both sides by walls 80.

Walls 80 may advantageously be made of glass or of ceramic materials.

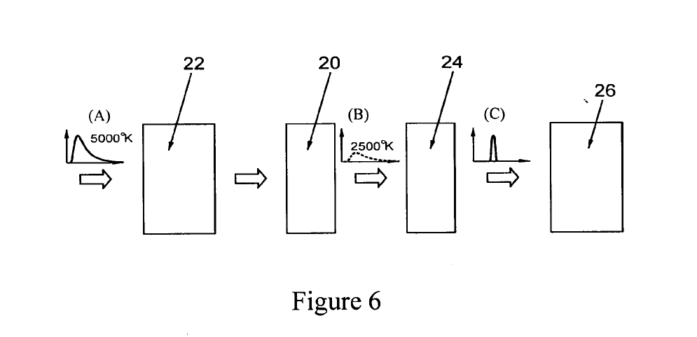

FIG. 6 is a schematic, graphical representation of the multiple-stage conversion of the solar spectrum to a preferred spectrum for a photovoltaic cell, according to an exemplary embodiment of the present invention. Spectrum (A) is an idealized electromagnetic spectrum produced by the sun. After the light is passed through optical device 22, this spectrum may be largely unaffected. Spectrum (B) is an idealized electromagnetic spectrum emitted by black-body 20, assuming black-body 20 has a generally round, smooth surface. Spectrum (C) is an idealization of an electromagnetic spectrum that has passed through optical device 24, which filters various wavelengths so as to provide photovoltaic cell 26 with photons within the requisite energy range.

The impact of filters on the emission of a black-body has been recognized recently by J. J. Greffet, et al., “Coherent emission of light by thermal sources”, Nature, 416, 61-64 (2002), and by M. Laroche et al., “Coherent Thermal Antenna Using a Photonic Crystal Slab”, Phys. Rev. Lett. 96, 123903 (2006). The authors demonstrate that the angular and spectral characteristics of the black-body emission are controlled by the grating at the surface of the black body. Using these or other techniques known in the art, a surface 20a of black-body 20 may be designed and adapted to produce a higher fraction of photons within the requisite energy range, with respect to Spectrum (B).

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

What is claimed is:

1. A spectrum manipulation device for increasing an energy conversion efficiency of a photovoltaic cell arrangement, the device comprising:
(a) a black body adapted to absorb an input electromagnetic energy having an input energy flux spectrum, and to emit a first output electromagnetic energy having a different, output energy flux spectrum, said black body behaving as a solid at a temperature of up to at least 1200K;
(b) a solid, at least partially transparent cover, facing a first side of said black body, said cover adapted to thermally insulate said black body from an ambient environment, and to receive light and direct said light towards said black body;
(c) an optical filter arrangement, facing a second side of said black body, and adapted to:
(i) receive said first output energy and emit a second output electromagnetic energy having a narrow, modified energy flux spectrum, with respect to said output energy flux spectrum of said black body, and
(ii) recycle at least a portion of said first output electromagnetic energy to said black body;
(d) at least one photovoltaic cell having a photon absorption surface, said surface disposed to be in optical communication with said optical filter arrangement, and
(e) a housing containing at least said black body and said optical filter arrangement, said housing adapted to thermally insulate said black body and to fix a position of said black body with respect to said optical filter arrangement,
and wherein said optical filter arrangement is further adapted to direct said second output energy having said modified spectrum towards said photon absorption surface.

2. The device of claim 1, further comprising:
a first sealed volume, disposed and thermally insulating between said black body and said cover, said sealed volume having a subatmospheric pressure below 10⁻⁴ torr.

3. The device of claim 2, further comprising:
a subatmospheric sealed volume, disposed and thermally insulating between said black body and said optical filter arrangement, said subatmospheric sealed volume having a subatmospheric pressure below 10⁻⁴ torr.

4. The device of claim 2, wherein said optical filter arrangement includes a Bragg filter.

5. The device of claim 1, wherein said black body is a mesoscopic black body having a thickness below 100 micrometers and having a plurality of nanostructures.

6. The device of claim 1, said housing having an inner surface contacting said black body, said inner surface having a heat transfer coefficient below 2.0 Wm¹K⁻¹ at 300K.

7. The device of claim 6, said housing including at least one ceramic material including a ceramic oxide.

8. The device of claim 7, said ceramic oxide selected from the group of ceramic oxides consisting of alumina, zirconia, and magnesia.

9. The device of claim 1, wherein said cover includes a Bragg filter.

10. The device of claim 2, wherein a grating is disposed on a surface of said black body.

11. The device of claim 10, wherein said grating is optically disposed between said black body and said optical filter arrangement.

12. The device of claim 1, wherein said optical filter arrangement is adapted whereby at least 80% of said modified energy flux spectrum lies within a range of 0.4 eV.

13. A spectrum manipulation device comprising:
(a) a black body adapted to absorb an input electromagnetic energy having an input energy flux spectrum, and to emit a first output electromagnetic energy having a different, output energy flux spectrum;
(b) a solid, at least partially transparent cover, facing a first side of said black body, said cover adapted to thermally insulate said black body from an environment, and to receive light and direct said light towards said black body;
(c) an optical filter arrangement, facing a second side of said black body, and having a Bragg filter adapted to:
(i) receive said first output energy;
(ii) recycle at least a portion of said output electromagnetic energy to said black body, and
(iii) emit a second output electromagnetic energy having a narrow, modified energy flux spectrum, with respect to said output energy flux spectrum of said black body; and
(d) a housing containing at least said black body and said optical filter arrangement, said housing adapted to thermally insulate said black body and to fix a position of said black body with respect to said optical filter arrangement.

14. The device of claim 13, further comprising:
a substantially transparent concentrating element, disposed whereby said cover is between said concentrating element and said black body, said concentrating element adapted to concentrate light and to direct said light to said cover.

15. The device of claim 13, further comprising:
a first sealed volume, disposed and thermally insulating between said black body and said cover, said sealed volume having a subatmospheric pressure below 0.1 torr; and
a second sealed volume, disposed and thermally insulating between said black body and said optical filter arrangement, said second sealed volume having a subatmospheric pressure below 10⁻⁴ torr.

16. The device of claim 15, wherein said cover includes a Bragg filter.

17. The device of claim 16, wherein a grating is disposed on a surface of said black body.

18. The device of claim 17, said grating optically disposed between said black body and said optical filter arrangement.

19. A method of increasing an energy conversion efficiency of a photovoltaic cell arrangement, the method comprising the steps of:
(a) providing the device of claim 1;
(b) disposing the device whereby said black body absorbs, from solar light, said input electromagnetic energy, and emits said first output electromagnetic energy;
(c) processing said first output energy in said filter arrangement to emit said second output electromagnetic energy having said modified spectrum and a third output electromagnetic energy;
(d) conveying said second output energy to said photovoltaic cell, and
(e) recycling at least a portion of said third output energy to said black body.

20. The method of claim 19, wherein said at least a portion of said third output energy is at least 20% of said third output energy.
